(19) United States
(12) Patent Application Publication
(10) Pub. No.: US 2004/0094827 A1
(43) Pub. Date: May 20, 2004

(54) Leadframe for semiconductor device, method for manufacturing semiconductor device using the same, semiconductor device using the same, and electronic equipment

(76) Inventor: Hideya Takakura, Kitakatsuragi-gun (JP)

Correspondence Address: BIRCH STEWART KOLASCH & BIRCH, PO BOX 747, FALLS CHURCH, VA, 22040-0747, US

(21) Appl. No.: 10/690,615

(22) Filed: Oct. 23, 2003

(30) Foreign Application Priority Data
Nov. 18, 2002 (JP) 2002-333717

(51) Int. Cl. H01L 23/495

(52) U.S. Cl. 257/666

(57) ABSTRACT

A leadframe to be used in a semiconductor device comprises a plurality of parallel first leads and a plurality of parallel second leads. The pitch of the first leads is different from that of the second leads, and the first leads are joined end-to-end with the second leads. To obtain a leadframe for DIP packages, the first leads are encapsulated in a package and the second leads are allowed to project from the package. To obtain a leadframe for SOP packages, the first leads and the second leads are allowed to project from a package and the second leads are cut off later.

### BACKGROUND OF THE INVENTION

1. Field of the Invention

The present invention relates to leadframes for semiconductor devices, a method for manufacturing semiconductor devices using the same, semiconductor devices using the same, and electronic equipments.

2. Conventional Art

Leadframes for semiconductor devices (e.g. photocoupling devices) include many variations such as for DIP (Dual Inline Package) packages and SOP (Small Outline Package) packages (see Japanese Patent Laid-open Publication No. H7-94657). A leadframe for DIP packages has leads to be inserted into holes in a substrate, these leads having a thickness of 0.25 mm at the tips and being spaced at a pitch of 2.54 mm. A leadframe for SOP packages has leads to be placed on a substrate surface, these leads having a thickness of about 0.15 to 0.20 mm at the tips and being spaced at a pitch of 1.27 mm.

FIG. 4A is a plan view of a photocoupling device using a conventional leadframe for DIP packages, and FIG. 4B depicts an internal structure of this photocoupling device. FIG. 5 is a flowchart which describes a process of manufacturing this photocoupling device.

In a conventional photocoupling device 101, a light-emitting element 102 and a light-receiving element 103 are respectively mounted on and die bonded to headers 104a, 105a of the leadframes 104, 105. The light-emitting element 102 and the light-receiving element 103 are also wire bonded to leads 104b, 105b of the leadframes 104, 105 by wires 106, 107, respectively. Then, for relaxation of stress, the light-emitting element 102 is pre-coated with a silicone resin 108. With the optical axes of the light-emitting element 102 and the light-receiving element 103 being aligned with each other, the leadframes 104, 105 are fixed in position. Next, as primary molding, a transparent epoxy resin 111 is molded to form an optical transmission path between the light-emitting element 102 and the light-receiving element 103. In this state, the leadframes 104, 105 are subjected to primary tie bar cut. Thereafter, as secondary molding (e.g. transfer molding), a light shading epoxy resin is molded to give a package 112. This packaged item undergoes exterior plating, secondary tie bar cut for the leadframes 104, 105, lead forming (forming of the leads 104b, 105b outside the package 112), withstand voltage test (examination of insulation between the light-emitting element 102 and the light-receiving element 103), electric characteristics test (measurement of various electric characteristics), marking, inspection of external appearance, and packing. Finally, the photocoupling device 101 is shipped as a commercial product.

Being designed for DIP packages, the leadframes 104, 105 have their leads 104b, 105b project downwardly so as to be inserted into holes in a substrate.

With respect to the secondary molding, it is possible to apply injection molding, casting or the like as well as transfer molding. Further, with respect to the primary molding for forming an optical transmission path between the light-emitting element 102 and the light-receiving element 103, a transparent silicone resin may be used instead of a transparent epoxy resin.

FIG. 6 is a flowchart which describes a process of manufacturing conventional leadframes for DIP packages.

A coiled metal plate (a plate of Cu, Fe or the like), as a leadframe material, is unwound and stamped by means of a stamping die, such that each of the leadframes can have a header, a lead and other parts (stamping step). Then, each leadframe is plated with silver at the header for mounting a element and at an area to be connected with the bonding wire (plating step). Next, the header and leads of each leadframe are bent and cut into a prescribed length (bending/cutting step). This cutting operation is performed when the leadframes are supplied in strip form, but omitted when they are supplied in reel form. Eventually, a reel of or a strip of leadframes are provided as commercial products.

Depending on the situation, the stamping step, the plating step and the bending/cutting step may be performed in different orders.

FIG. 7A is a plan view of a photocopying device using a conventional leadframe for SOP packages, and FIG. 7B depicts an internal structure of this photocoupling device. FIG. 8 is a flowchart which describes a process of manufacturing this photocoupling device. Concerning the photocoupling device of FIG. 7A and FIG. 7B, elements which serve the same operations as those mentioned in FIG. 4A and FIG. 4B are indicated by the same reference numerals.

As compared with the photocoupling device 101 in FIG. 4A and FIG. 4B, a photocoupling device 121 employs leadframes 124, 125 in place of the leadframes 104, 105 of the photocoupling device 101 and adopts a package 122 of different configuration.

Being designed for SOP packages, the leadframes 124, 125 have their leads 124b, 125b bent so as to be in contact with a wiring pattern on the substrate surface.

The leadframe for SOP packages is manufactured by the same process for the leadframe for DIP packages as described in FIG. 6.

Incidentally, assembly processes for electronic components are recently divided into two dominant trends. One is to promote automation by using mounters, whereas the other is to encourage manual operations which take advantage of a cheap workforce in Asian countries, mainly in China.

The former process, in which mounters automatically mount electronic components on substrates by reflow or other manner, requires electronic components using leadframes for small SOP packages. On the other hand, the latter process, in which human workers manually insert leads of each electronic component into holes in substrates, requires electronic components using leadframes for DIP packages.

From another point of view, semiconductor devices (e.g. photocoupling device) using leadframes for DIP packages and semiconductor devices (e.g. photocoupling device) using leadframes for SOP packages have to be manufactured in separate production lines even if their electric characteristics are totally identical. Therefore, production plans for these semiconductor devices should be adjusted independently of each other, according to the market situation.

From still another point of view, leadframes for DIP packages and those for SOP packages are different in lead pitch and thickness at the lead tips, as mentioned earlier. Therefore, manufacture of these leadframes requires individual stamping dies and bending dies.

However, the proportion of semiconductor devices using leadframes for DIP packages and those using leadframes for SOP packages demanded in the market are changing radically. Under such circumstances, setting of production plans for the respective semiconductor devices has been a difficult task. It is often the case that manufacturers may be flooded with orders beyond their production capacities or may fail to cater for unexpected orders.

### SUMMARY OF THE INVENTION

The present invention is made in view of the above problems related to the conventional technology. An object of the present invention is to provide leadframes which are adjustable to more than one types of packages.

Another object of the present invention is to provide a method for manufacturing semiconductor devices using the leadframes of the present invention, semiconductor devices using the same, and electronic equipments.

In order to solve the above problems, the present invention is directed to a leadframe to be used in a semiconductor device, which comprises a plurality of parallel first leads and a plurality of parallel second leads. The pitch of the first leads is different from that of the second leads, and the first leads are joined end-to-end with the second leads.

According to the thus arranged invention, the pitch of the first leads is different from that of the second leads, and the first leads are joined end-to-end with the second leads. In the steps of mounting a semiconductor element on the leadframe and encapsulating the semiconductor element in a package, if the first leads are encapsulated in the package and only the second leads are allowed to project from the package, a semiconductor device equipped with the second leads is obtained. If both the first leads and the second leads are allowed to project from the package and the second leads are cut off later, a semiconductor device equipped with the first leads is obtained. Namely, while using a common leadframe component, it is possible to set either of two types of lead pitches. Sharing of a leadframe component decreases a material cost and material types, and also simplifies component control. In addition, a single production line can serve for two types of semiconductor devices which have different lead pitches. Sharing of a production line enables changes of production plans for the two types of semiconductor devices without difficulty, achieves stable supply of semiconductor devices and reduction of capital investment cost, and provides semiconductor devices at a lower cost.

In the present invention, at least either of the first leads or the second leads may have their thickness reduced.

As for the method for manufacturing a semiconductor device, the method according to the present invention comprises the steps of mounting a semiconductor element on the leadframe of the present invention, and encapsulating the semiconductor element in a package. In this method, the dimension of the package for encapsulation is set such that at least either of the first leads or the second leads project from the package.

The manufacture method of the present invention can also accomplish the same operations and effects as achieved by the leadframe of the present invention.

Further in the present invention, at least either of the first leads or the second leads may be squeezed by a mold for molding the package and have their thickness reduced.

In the case where at least either of the first leads and the second leads are made thinner by a mold for molding the package and have their thickness reduced, there is no need to include a special step for reducing their thickness, thereby avoiding cost increase.

Furthermore, the present invention encompasses not only leadframes and a method for manufacturing semiconductor devices using the same, but also semiconductor devices using the same and electronic equipments.

The semiconductor devices include photocouplers, ICs, LSIs, and the like.

The electronic equipments include DVDs, CDs, MDs and other playback equipment, TVs, VTRs, power equipment, inverter control equipment, and the like.

### BRIEF DESCRIPTION OF THE DRAWINGS

FIG. 1A concerns a step for manufacturing a photocoupling device which utilizes an embodiment of a leadframe according to the present invention, showing the leadframe with a semiconductor element mounted thereon.

FIG. 1B concerns a step for manufacturing a photocoupling device which utilizes an embodiment of a leadframe according to the present invention, in the state after completion of primary molding and primary tie bar cut.

FIG. 1C concerns a step for manufacturing a photocoupling device which utilizes an embodiment of a leadframe according to the present invention, in the state after completion of transfer molding.

FIG. 1D concerns a step for manufacturing a photocoupling device which utilizes an embodiment of a leadframe according to the present invention, in the state after completion of secondary tie bar cut.

FIG. 2 is a perspective view showing a leadframe of this embodiment.

FIG. 3A concerns a step for manufacturing a different photocoupling device which utilizes a leadframe according to this embodiment, in the leadframe with a semiconductor element mounted thereon.

FIG. 3B concerns a step for manufacturing a different photocoupling device which utilizes a leadframe according to this embodiment, in the state after completion of primary molding and primary tie bar cut.

FIG. 3C concerns a step for manufacturing a different photocoupling device which utilizes a leadframe according to this embodiment, in the state after completion of transfer molding.

FIG. 3D concerns a step for manufacturing a different photocoupling device which utilizes a leadframe according to this embodiment, in the state after completion of secondary tie bar cut.

FIG. 4A is a plan view of a photocoupling device using a conventional leadframe for DIP packages.

FIG. 4B shows an internal structure of a photocoupling device using a conventional leadframe for DIP packages.

FIG. 5 is a flowchart describing a process for manufacturing a photocoupling device using a conventional leadframe for DIP packages.

FIG. 6 is a flowchart describing a process for manufacturing conventional leadframes for DIP packages.

FIG. 7A is a plan view of a photocoupling device using a conventional leadframe for SOP packages.

FIG. 7B shows an internal structure of a photocoupling device using a conventional leadframe for SOP packages.

FIG. 8 is a flowchart describing a process for manufacturing a photocoupling device using a conventional leadframe for SOP packages.

### DESCRIPTION OF PREFERRED EMBODIMENTS

Referring to the attached drawings, an embodiment of the present invention is hereinafter described in detail.

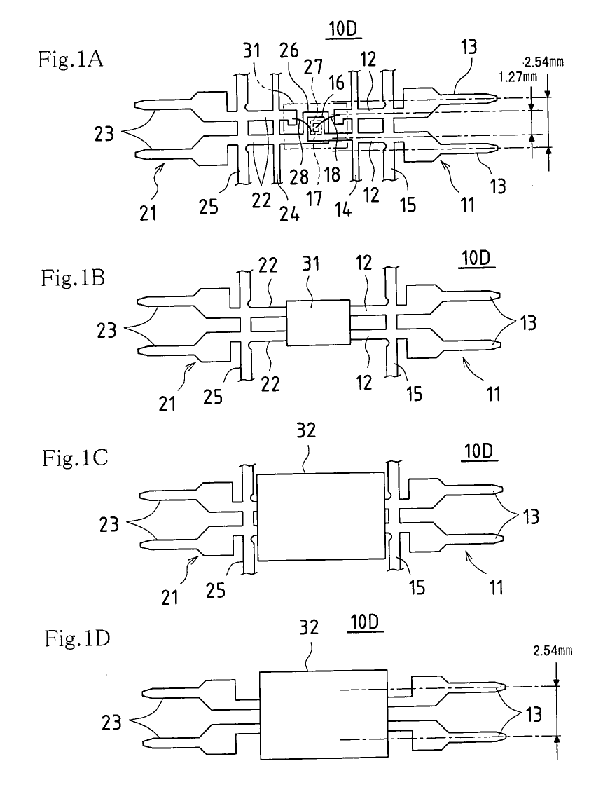

FIG. 1A to FIG. 1D concern steps for manufacturing a photocoupling device which utilizes an embodiment of a leadframe according to the present invention. FIG. 1A shows the leadframe, with a semiconductor element mounted. FIG. 1B shows the state after completion of primary molding and primary tie bar cut. FIG. 1C shows the state after completion of transfer molding. FIG. 1D shows the state after completion of secondary tie bar cut. As illustrated, a photocoupling device 10D is composed of a light-emitting side leadframe 11 and a light-receiving side leadframe 21.

Referring to FIG. 1A, the light-emitting side leadframe 11 has parallel first leads 12, parallel second leads 13, tie bars 14, 15 which join the first leads 12, and a header 16 provided at an end of one of the first leads 12. The first leads 12 are joined one by one with the second leads 13.

The thickness of the light-emitting side leadframe 11 is 0.25 mm, following the DIP package specification. The pitch of the first leads 12 is set to 1.27 mm, following the SOP package specification. The pitch of the second leads 13 is set to 2.54 mm, following the DIP package specification.

As shown in FIG. 1A, the light-receiving side leadframe 21 has parallel first leads 22, parallel second leads 23, tie bars 24, 25 which join the first leads 22, and a header 26 provided at an end of one of the first leads 22. The first leads 22 are joined one by one with the second leads 23.

Similar to the light-emitting side leadframe 11, the thickness of the light-receiving side leadframe 21 is 0.25 mm, following the DIP package specification. The pitch of the first leads 22 is set to 1.27 mm, following the SOP package specification. The pitch of the second leads 23 is set to 2.54 mm, following the DIP package specification.

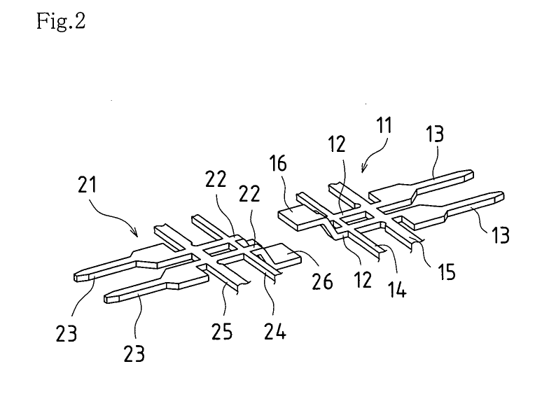

The first leads 12 of the light-emitting side leadframe 11 are bent in advance as shown in FIG. 2. In this light-emitting side leadframe 11, a light-emitting element 17 is mounted and die-bonded on the header 16 which is provided at one of the first leads 12, as illustrated in FIG. 1A. The light-emitting element 17 is further wire-bonded to the other first lead 12 via a wire 18. For the purpose of stress relaxation, the thus bonded light-emitting element 17 may be pre-coated with a silicone resin.

Likewise, the first leads 22 of the light-receiving side leadframe 21 are bent in advance as shown in FIG. 2. In this light-receiving side leadframe 21, a light-receiving element 27 is mounted and die-bonded on the header 26 which is provided at one of the first leads 22, as illustrated in FIG. 1A. The light-receiving element 27 is further wire-bonded to the other first lead 22 via a wire 28.

Thus, the light-emitting element 17 is mounted on the light-emitting side leadframe 11, and the light-receiving element 27 is mounted on the light-receiving side leadframe 21. With the optical axes of the light-emitting element 17 and the light-receiving element 27 being aligned with each other, the light-emitting side leadframe 11 and the light-receiving side leadframe 21 are fixed in position. In this state, a transparent epoxy resin 31 is molded, as primary molding, to form an optical transmission path between the light-emitting element 17 and the light-receiving element 27.

Thereafter, the tie bar 14 of the light-emitting side leadframe 11 and the tie bar 24 of the light-receiving side leadframe 21 are cut in the manner shown in FIG. 1B. Further, a light shading epoxy resin is transfer molded to form a package 32 as shown in FIG. 1C.

Usually, while these steps are conducted, multiple first leads 12 and multiple second leads 13 of the light-emitting side leadframe 11 are connected by the tie bars 14, 15, and multiple first leads 22 and multiple second leads 23 of the light-receiving side leadframe 21 are connected by the tie bars 24,25. Hence, a plurality of photocoupling devices 10D are manufactured in one process.

Finally, the tie bar 15 of the light-emitting side leadframe 11 and the tie bar 25 of the light-receiving side leadframe 21 are cut in the manner shown in FIG. 1D, so that the photocoupling devices 10D are separated one by one.

Afterwards, each of the photocoupling devices 10D undergoes lead forming (forming of the second leads 13 of the light-emitting side leadframe 11 and the second leads 23 of the light-receiving side leadframe 21), withstand voltage test (examination of insulation between the light-emitting element 17 and the light-receiving element 27), electric characteristics test (measurement of various electric characteristics), marking, inspection of external appearance, and packing, before shipped as a commercial product. As for the lead forming, the second leads 13, 23 are formed to such a configuration that they can be inserted into holes in a substrate.

As apparent from the photocoupling device 10D in FIG. 1D, the second leads 13 of the light-emitting side leadframe 11 and the second leads 23 of the light-receiving side leadframe 21 serve to establish external connection.

As mentioned earlier, the thickness of the light-emitting side leadframe 11 and the light-receiving side leadframe 21 is 0.25 mm, following the DIP package specification. The pitch of the second leads 13, 23 is set to 2.54 mm, following the DIP package specification.

Namely, the external connection leads in this photocoupling device 10D are made to the DIP package specification. Hence, the photocoupling device 10D can be classified into a photocoupling device using a leadframe for DIP packages.

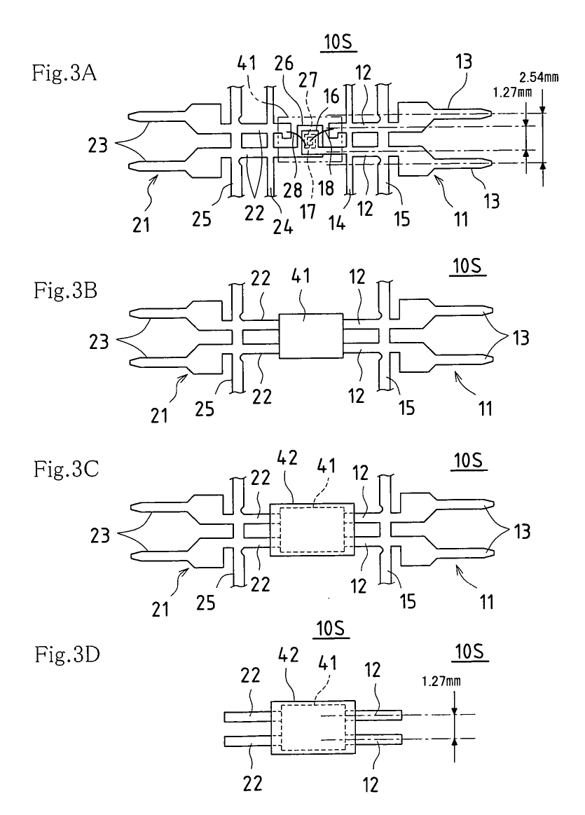

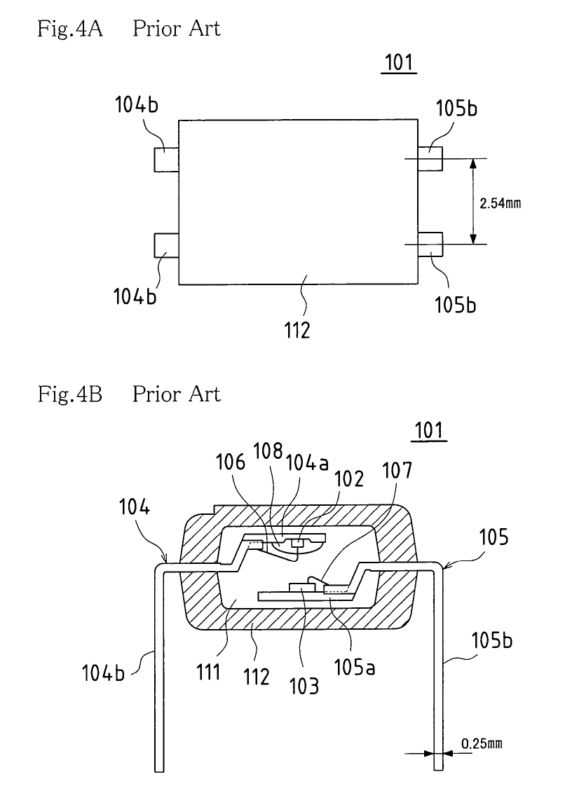

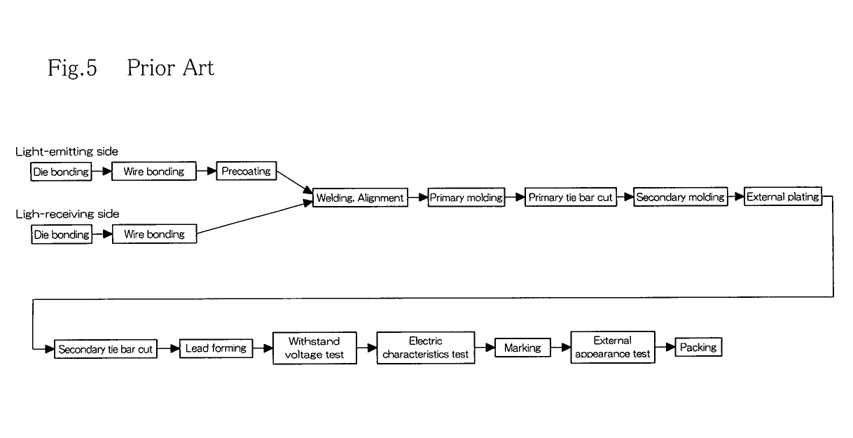

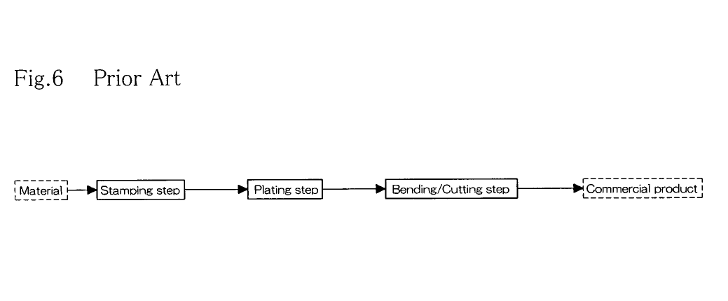

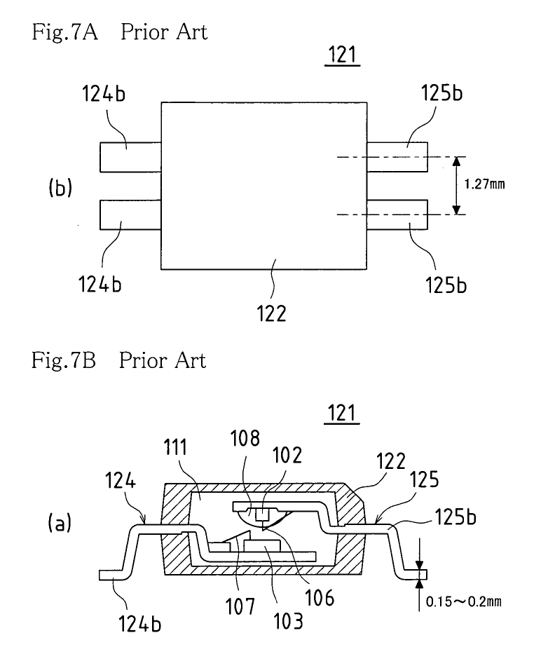

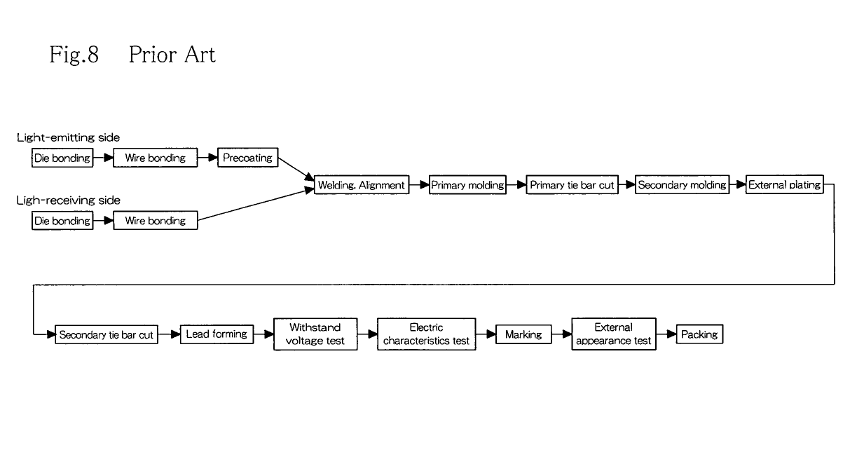

FIG. 3A to FIG. 3D concern steps for manufacturing a different photocoupling device which utilizes a leadframe of this embodiment. FIG. 3A shows the leadframe, with a semiconductor element mounted. FIG. 3B shows the state after completion of primary molding and primary tie bar cut. FIG. 3C shows the state after completion of transfer molding. FIG. 3D shows the state after completion of secondary tie bar cut. In FIG. 3A to FIG. 3D, elements which provide the same operations as those mentioned in FIG. 1A to FIG. 1D are indicated by the same reference numerals.

Just as the photocoupling device 10D in FIG. 1, a photocoupling device 10S is composed of a light-emitting side leadframe 11, a light-receiving side leadframe 21, a light-emitting element 17, a light-receiving element 27 and the like. In other words, the photocoupling device 10S and the photocoupling device 10D share most of the components.

Nevertheless, the photocoupling device 10S and the photocoupling device 10D require individual molds, with respect to the primary mold for molding a transparent epoxy resin by primary molding so as to form an optical transmission path between the light-emitting element 17 and the light-receiving element 27, and with respect to the secondary mold for transfer molding a light shading epoxy resin to form a package.

Referring to the photocoupling device 10S in FIG. 3A, the light-emitting element 17 is mounted on the light-emitting side leadframe 11, and the light-receiving element 27 is mounted on the light-receiving side leadframe 21. With the optical axes of the light-emitting element 17 and the light-receiving element 27 being aligned with each other, the light-emitting side leadframe 11 and the light-receiving side leadframe 21 are fixed in position. In this state, a transparent epoxy resin 41 is molded, as primary molding, to form an optical path between the light-emitting element 17 and the light-receiving element 27.

During the primary molding, the first leads 12 of the light-emitting side leadframe 11 and the first leads 22 of the light-receiving side leadframe 21 are squeezed by the primary mold. As a result, the thickness of the first leads 12, 22, which is originally 0.25 mm following the DIP package specification, is reduced to about 0.15 to 0.20 mm so as to conform to the SOP package specification.

Thereafter, the tie bar 14 of the light-emitting side leadframe 11 and the tie bar 24 of the light-receiving side leadframe 21 are cut in the manner shown in FIG. 3B. Further, a light shading epoxy resin is transfer molded to form a package 42 as shown in FIG. 3C.

Usually, while these steps are conducted, multiple first leads 12 and multiple second leads 13 of the light-emitting side leadframe 11 are connected by the tie bars 14, 15, and multiple first leads 22 and multiple second leads 23 of the light-receiving side leadframe 21 are connected by the tie bars 24, 25. Hence, a plurality of photocoupling devices 10S are manufactured in one process.

Finally, the tie bar 15 of the light-emitting side leadframe 11 and the tie bar 25 of the light-receiving side leadframe 21 are cut in the manner shown in FIG. 3D, so that the photocoupling devices 10S are separated one by one. The second leads 13 of the light-emitting side leadframe 11 and the second leads 23 of the light-receiving side leadframe 21 are cut at the same time.

Afterwards, each of the photocoupling devices 10S undergoes lead forming (forming of the first leads 12 of the light-emitting side leadframe 11 and the first leads 22 of the light-receiving side leadframe 21), withstand voltage test (examination of insulation between the light-emitting element 17 and the light-receiving element 27), electric characteristics test (measurement of various electric characteristics), marking, inspection of external appearance, and packing, before shipped as a commercial product. As for the lead forming, the first leads 12, 22 are formed to such a configuration that they can be mounted on a substrate surface.

As apparent from the photocoupling device 10S in FIG. 3D, the first leads 12 of the light-emitting side leadframe 11 and the first leads 22 of the light-receiving side leadframe 21 serve to establish external connection.

As mentioned earlier, the pitch of the first leads 12 of the light-emitting side leadframe 11 and the first leads 22 of the light-receiving side leadframe 21 is set to 1.27 mm, following the SOP package specification. The thickness of the first leads 12, 22 is reduced during the primary molding step to about 0.15 to 0.20 mm, following the SOP package specification.

Namely, the external connection leads in this photocoupling device 10S are made to the SOP package specification. Hence, the photocoupling device 10S can be classified into a photocoupling device using a leadframe for SOP packages.

With use of the leadframe of this embodiment, it is possible to obtain a leadframe for DIP packages by letting the second leads 13, 23 project from the package, or to obtain a leadframe for SOP packages by cutting the second leads 13, 23 and letting the first leads 12, 22 project from the package. Hence, a leadframe for DIP packages and the one for SOP packages, which have conventionally been made from different leadframe components, can be made from one type of common leadframe component. It is also possible to decrease a material cost and material types and to simplify component control.

Moreover, comparison between FIGS. 1A-1D and FIGS. 3A-3D reveals an advantage that DIP packages and SOP packages can share a production line. Therefore, it is easily possible to change production plans for the two types of photocoupling devices which are distinguished by lead pitches. Besides, it is possible to achieve stable supply of photocoupling devices and reduction of capital investment cost and also to provide photocoupling devices at a lower cost.

It should be understood that the present invention is not limited to the above embodiment but may be modified in various manners. For example, to reduce the thickness of the first leads 12, 22 in the above embodiment, the first leads are squeezed by the primary mold during the primary molding step. Instead, the first leads 12, 22 may be made thinner in advance by other known methods. In addition, the primary mold and the secondary mold may be shared in the processes of manufacturing the photocoupling device 10D and the photocoupling device 10S.

The leadframe according to the present invention is applicable not only to photocoupling devices but also to other semiconductor devices such as ICs and LSIs. The present invention further encompasses electronic equipments which contain semiconductor devices using the leadframes. As the electronic equipments, there may be mentioned DVDs, CDs, MDs and other playback equipment, TVs, VTRs, power equipment, inverter control equipment, and the like.

The invention may be embodied in other specific forms without departing from the spirit or essential characteristics thereof. The above embodiment is therefore to be considered in all respects as illustrative and not restrictive, the scope of the invention being indicated by the appended claims rather than by the foregoing description. All changes which come within the meaning and range of equivalency of the claims are therefore intended to be embraced therein.

This application is based on Patent Application No. 2002-333717 filed in Japan, the contents of which are incorporated hereinto by reference. Likewise, the contents of all references cited herein are incorporated hereinto by reference.

What is claimed is:

1. A leadframe to be used in a semiconductor device,
which comprises a plurality of parallel first leads and a plurality of parallel second leads,
wherein the pitch of the first leads is different from that of the second leads, and the first leads are joined end-to-end with the second leads.

2. The leadframe according to claim 1,
wherein at least either of the first leads or the second leads have their thickness reduced.

3. A method for manufacturing a semiconductor device using a leadframe,
which comprises the steps of mounting a semiconductor element on the leadframe according to claim 1, and encapsulating the semiconductor element in a package,
wherein the dimension of the package for encapsulation is set such that at least either of the first leads or the second leads project from the package.

4. The method for manufacturing a semiconductor device using a leadframe, according to claim 3,
wherein at least either of the first leads or the second leads are squeezed by a mold for molding the package and have their thickness reduced.

5. A semiconductor device using the leadframe according to claim 1.

6. An electronic equipment using the semiconductor device according to claim 5.
